(19) United States
(12) Patent Application Publication
(10) Pub. No.: US 2025/0374760 A1
(43) Pub. Date: Dec. 4, 2025

(54) DISPLAY DEVICE AND METHOD OF MANUFACTURING THE SAME

(71) Applicant: Samsung Display Co., Ltd., Yongin-Si, (KR)

(72) Inventors: Jong Oh SEO, Yongin-si (KR); Dong-Min LEE, Yongin-si (KR); DONGGYU JIN, Yongin-si (KR)

(21) Appl. No.: 19/057,975

(22) Filed: Feb. 20, 2025

(30) Foreign Application Priority Data
May 28, 2024 (KR) 10-2024-0069573

(51) Int. Cl. H10K 59/121; H10D 86/40; H10K 59/12; H10K 59/131

(52) U.S. Cl. CPC H10K 59/1213; H10D 86/421; H10K 59/1201; H10K 59/131

(57) ABSTRACT

A display device is disclosed that includes a substrate including a first base layer and a first barrier layer, a metal layer disposed on the substrate, a buffer layer disposed on the metal layer, and a semiconductor layer disposed on the buffer layer, wherein the first base layer includes a first opening, and a side surface of the metal layer is disposed inside the first opening in a plan view.

### CROSS-REFERENCE TO RELATED APPLICATION

This application claims priority to and the benefit of Korean Patent Application No. 10-2024-0069573 filed at the Korean Intellectual Property Office on May 28, 2024, the entire contents of which are incorporated herein by reference.

### BACKGROUND

### (a) Technical Field

The present disclosure relates to a display device and a method of manufacturing the same.

### (b) Description of the Related Art

Display devices display images on screens, and may include liquid crystal displays (LCD), organic light emitting diode (OLED) displays, and the like. Display devices may be used in various electronic devices such as mobile phones, navigation devices, digital cameras, electronic books, portable game machines, and various terminals.

In a display-device manufacturing process, an excimer laser annealing (ELA) method or a solid laser annealing (SLA) method is often used as a method to crystallize amorphous silicon to form polycrystalline silicon. The SLA method is a process that amplifies and generates high energy using a solid-state laser source, enabling heat treatment with high laser energy.

### SUMMARY

Embodiments may provide a display device in which a film of a semiconductor layer has been prevented from bursting when crystallizing the semiconductor layer, and a method of manufacturing the same.

A display device according to an embodiment includes a substrate including a first base layer and a first barrier layer, a metal layer disposed on the substrate, a buffer layer disposed on the metal layer, and a semiconductor layer disposed on the buffer layer, wherein the first base layer includes a first opening, and a side surface of the metal layer is disposed inside the first opening in a plan view.

The semiconductor layer may include a convex portion corresponding to the side surface of the metal layer and an upper surface of the metal layer, and a side surface of the convex portion may be disposed inside the first opening in a plan view.

A second base layer disposed below the first base layer may be further included.

A thickness of the first base layer may be thinner than a thickness of the second base layer.

The thickness of the first base layer may be half the thickness of the second base layer.

The second base layer may include a second opening.

The side surface of the metal layer may be disposed inside the second opening in a plan view.

An edge of the first opening may be aligned with an edge of the second opening corresponding to the first opening.

An edge of the first opening may not be aligned with an edge of the second opening.

The first opening may not overlap the second opening.

A side surface of the convex portion may be disposed inside the second opening in a plan view.

A method of manufacturing a display device according to an embodiment includes forming a first base layer, forming a first opening in the first base layer by patterning the first base layer, forming a first barrier layer on the first base layer, forming a first barrier layer on the first base layer, forming a buffer layer on the metal layer, and forming a semiconductor layer on the buffer layer, wherein a side surface of the metal layer is disposed inside the first opening in a plan view.

The forming of the first opening may include forming a first opening by irradiating a laser to an upper surface or a lower surface of the first base layer.

Before forming the first base layer, forming a second base layer, and forming a second barrier layer on the second base layer may be further included.

The thickness of the first base layer may be thinner than the thickness of the second base layer.

After the forming of the second base layer, forming a second opening by patterning the second base layer may be further included.

The forming of the second opening may include forming a second opening by irradiating a laser to an upper surface or a lower surface of the second base layer.

The side surface of the metal layer may be disposed inside the second opening in a plan view.

An edge of the first opening may be aligned with an edge of the second opening corresponding to the first opening.

The first opening may not overlap the second opening.

According to embodiments, it is possible to provide a display device capable of preventing film bursting of a semiconductor layer when crystallizing the semiconductor layer, and a method of manufacturing the same.

### BRIEF DESCRIPTION OF THE DRAWINGS

FIG. 1 is a cross-sectional view illustrating a part of a display area in a display device according to an embodiment.

FIG. 2 is a cross-sectional view illustrating a part of a display area in a display device according to an embodiment.

FIG. 3 is a plan view illustrating a part of a display area in a display device according to an embodiment.

FIGS. 4, 5, and 6 are cross-sectional views each illustrating a part of a display area in a display device according to an embodiment.

FIGS. 7, 8, and 9 are cross-sectional views each illustrating a part of a display area in a display device according to an embodiment.

FIG. 10 is a cross-sectional view illustrating a part of a display area in a display device according to a comparative example.

FIG. 11 is a graph showing the temperatures of a semiconductor layer, a buffer layer, and a substrate of a display device according to an embodiment shown in FIG. 5.

FIG. 12 is a graph showing the temperatures of a semiconductor layer, a buffer layer, and a substrate of a display device according to the comparative example shown in FIG. 10.

FIG. 13 is a graph showing the temperature of a buffer layer of a display device according to the embodiment shown in FIG. 5.

FIG. 14 is a graph showing the temperature of a buffer layer of a display device according to another embodiment shown in FIG. 7.

FIG. 15 is a graph showing the temperature of a buffer layer of a display device according to the comparative example shown in FIG. 10.

FIG. 16 is a photograph showing a planar shape of a display device according to an embodiment.

FIG. 17 is a photograph showing a cross-sectional shape of a display device according to an embodiment.

FIG. 18 is a photograph showing a planar shape of a display device according to the comparative example shown in FIG. 10.

FIG. 19 is a photograph showing a cross-sectional shape of a display device according to the comparative example shown in FIG. 10.

FIG. 20 is a block diagram of an electronic device according to an embodiment.

FIG. 21 shows schematic diagrams of electronic devices according to various embodiments.

### DETAILED DESCRIPTION OF THE EMBODIMENTS

The present disclosure will be described in detail hereinafter with reference to the accompanying drawings, in which embodiments of the present disclosure are shown. As those skilled in the art would realize, the described embodiments may be modified in various different ways, all without departing from the spirit or scope of the present disclosure.

The drawings and description are to be regarded as illustrative in nature and not restrictive, and like reference numerals designate like elements throughout the specification.

The size and thickness of each constituent element in the drawings are arbitrarily illustrated for better understanding and ease of description, and the following embodiments are not limited thereto. In the drawings, the thickness of layers, films, panels, regions, etc., are exaggerated for clarity. In the drawings, the thickness of some layers and regions may be exaggerated for ease of description.

It should be understood that when an element such as a layer, film, region, or substrate is referred to as being “on” another element, it can be directly on the other element or intervening elements may also be present. In contrast, when an element is referred to as being “directly on” another element, there are no intervening elements present. Further, when an element is referred to as being “on” or “above” a reference element, it can be disposed above or below the reference element, and it is not necessarily referred to as being disposed “on” or “above” it in a direction opposite to gravity.

In addition, unless explicitly stated to the contrary, the words “comprise” and “include” as well as variations such as “comprises” and “comprising” should be understood to imply the inclusion of stated elements but not the exclusion of any other elements.

As used herein, the word “or” means logical “or” so that, unless the context indicates otherwise, the expression “A, B, or C” means “A and B and C,” “A and B but not C,” “A and C but not B,” “B and C but not A,” “A but not B and not C,” “B but not A and not C,” and “C but not A and not B.”

In addition, the phrase “in a plan view” means a view from a position above the object (e.g., from the top), and the phrase “on a cross-section” means a view of a cross-section of the object which is vertically cut from the side.

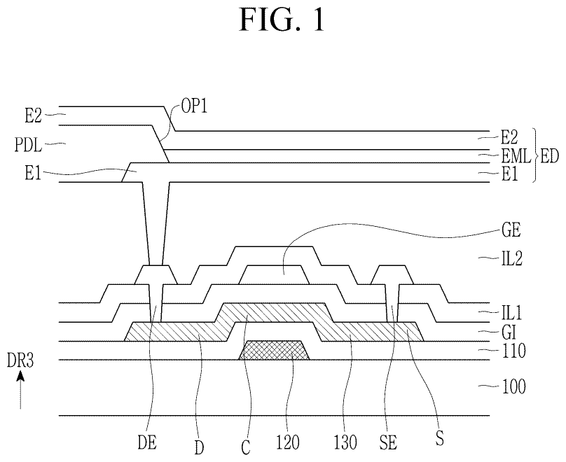

Hereinafter, a schematic structure of a display device according to an embodiment will be described with reference to FIG. 1. FIG. 1 is a cross-sectional view illustrating a part of a display area in a display device according to an embodiment.

Referring to FIG. 1, a substrate 100 may include a material with rigid properties such as glass, or a flexible material made of a polymer such as plastic or polyimide. Depending on the embodiment, the substrate 100 may have a single-layer or multi-layer structure containing the above materials. For example, the substrate 100 may include one or more base layers and one or more barrier layers, and the base layers and barrier layers may be alternately stacked. The barrier layer may prevent moisture, oxygen, etc. from penetrating.

A buffer layer 110 may be disposed on the substrate 100. In this specification, the directions in which the substrate 100 extends in the planar view are referred to as a first direction DR1 and a second direction DR2, and the direction in which layers are stacked on the substrate 100 is referred to as a third direction DR3.

The buffer layer 110 may include an inorganic material—for example, an inorganic insulating material such as silicon nitride (SiNx), silicon oxide (SiOx), or silicon oxynitride (SiOxNy). Depending on the embodiment, the buffer layer 110 may have a single-layer or multi-layer structure including the above inorganic insulating materials. The buffer layer 110 may flatten the surface of the substrate 100 and block the penetration of impure elements. The buffer layer 110 may contain hydrogen.

A metal layer 120 may be disposed on the substrate 100. The metal layer 120 may be disposed between the substrate 100 and the buffer layer 110. The metal layer 120 may include a metal or metal alloy such as copper (Cu), molybdenum (Mo), aluminum (Al), silver (Ag), chromium (Cr), tantalum (Ta), and titanium (Ti). The metal layer 120 may be formed of a single layer or multiple layers.

A semiconductor layer 130 may be disposed on the buffer layer 110. The semiconductor layer 130 may include any one of amorphous silicon, polycrystalline silicon, and oxide semiconductor. For example, the semiconductor layer 130 may include polysilicon, and more specifically, low-temperature polysilicon (LTPS). The semiconductor layer 130 may include a channel region C, a source region S, and a drain region D, which are divided depending on whether they are doped with impurities. The source region S and drain region D may have conductive characteristics corresponding to the conductors.

During a manufacturing process, a laser irradiates to an amorphous silicon layer of the semiconductor layer 130 to form a polycrystalline silicon layer. For example, a solid laser annealing (SLA) method, which generates a short-wavelength, high-power, and high-efficiency laser beam, may be used. The SLA method is a process that amplifies and generates high energy using a solid-state laser source and may provide heat treatment with the high laser energy. In the process of crystallizing the amorphous silicon layer of the semiconductor layer 130 into a polycrystalline silicon layer, heat energy may be generated.

A gate insulating layer GI may be disposed on the semiconductor layer 130. The gate insulating layer GI may cover the semiconductor layer 130 and the substrate 100. The gate insulating layer GI may include an inorganic insulating material such as silicon nitride (SiNx), silicon oxide (SiOx), or silicon oxynitride (SiOxNy). The gate insulating layer GI may have a single-layer or multi-layer structure containing the above inorganic insulating materials.

A gate electrode GE may be disposed on the gate insulating layer GI. The gate electrode GE may include a metal or metal alloy such as copper (Cu), molybdenum (Mo), aluminum (Al), silver (Ag), chromium (Cr), tantalum (Ta), and titanium (Ti). The gate electrode GE may be formed of a single layer or multiple layers. The region of the semiconductor layer 130 that overlaps the gate electrode GE in a plan view may be the channel region C.

A first insulating layer IL1 may be disposed on the gate electrode GE. The first insulating layer IL1 may include an inorganic insulating material such as silicon nitride (SiNx), silicon oxide (SiOx), or silicon oxynitride (SiOxNy). The first insulating layer IL1 may have a single-layer or multi-layer structure containing the above inorganic insulating materials.

A source electrode SE and a drain electrode DE may be disposed on the first insulating layer IL1. The source electrode SE and the drain electrode DE are respectively connected to the source region S and the drain region D of the semiconductor layer 130 through openings formed in the first insulating layer IL1 and the gate insulating layer GI. Accordingly, the above-described semiconductor layer 130, gate electrode GE, source electrode SE, and drain electrode DE form one transistor. Depending on the embodiment, a transistor may include the source region S and the drain region D of the semiconductor layer 130 but not the source electrode SE and the drain electrode DE.

The source electrode SE and the drain electrode DE may include metals or metal alloys such as aluminum (Al), copper (Cu), silver (Ag), gold (Au), platinum (Pt), palladium (Pd), nickel (Ni), molybdenum (Mo), tungsten (W), titanium (Ti), chromium (Cr), and tantalum (Ta). The source electrode SE and the drain electrode DE may be formed of a single layer or multiple layers. The source electrode SE and the drain electrode DE according to another embodiment may have a triple-layer structure including an upper layer, a middle layer, and a lower layer, wherein the upper layer and the lower layer may include titanium (Ti) and the middle layer may include aluminum (Al).

A second insulating layer IL2 may be disposed on the source electrode SE and the drain electrode DE. The second insulating layer IL2 may cover the source electrode SE and the drain electrode DE. The second insulating layer IL2 is for planarizing the surface of the substrate 100 on which the transistor is installed, and may be an organic insulating layer, and the second insulating layer IL2 may include one or more materials selected from the group consisting of polyimide, polyamide, acrylic resin, benzocyclobutene, and phenolic resin.

A first electrode E1 may be disposed on the second insulating layer IL2. The first electrode E1, also referred to as an anode electrode, may be formed of a single layer containing a transparent conductive oxide layer or a metal material, or multiple layers containing them. The transparent conductive oxide layer may include indium tin oxide (ITO), poly-ITO, indium zinc oxide (IZO), indium gallium zinc oxide (IGZO), and indium tin zinc oxide (ITZO). Metal materials may include silver (Ag), molybdenum (Mo), copper (Cu), gold (Au), and aluminum (Al).

The first electrode E1 may be physically and electrically connected to the drain electrode DE through an opening in the second insulating layer IL2. Accordingly, the first electrode E1 may receive the output current to be transmitted from the drain electrode DE to a light emitting layer EML, which will be described later.

A pixel defining layer PDL and a spacer (not shown) may be disposed on the first electrode E1 and the second insulating layer IL2. The pixel defining layer PDL includes a pixel opening OP1 that overlaps at least a part of the first electrode E1. At this time, the pixel opening OP1 may overlap the center of the first electrode E1 and may not overlap the edge of the first electrode E1. Accordingly, the planar size of the pixel opening OP1 may be smaller than the planar size of the first electrode E1. The pixel defining layer PDL may partition the formation position of the light emitting layer EML so that the light emitting layer EML is disposed on the exposed portion of the upper surface of the first electrode E1. The pixel opening OP1 may define the light emitting region of each pixel.

Each of the pixel defining layer PDL and the spacer may be an organic insulating layer containing one or more materials selected from the group consisting of polyimide, polyamide, acrylic resin, benzocyclobutene, and phenol resin, and depending on the embodiment, the pixel defining layer PDL may be formed of a black pixel defining layer containing black pigment.

The light emitting layer EML may be disposed in the pixel opening OP1 partitioned by the pixel defining layer PDL. The light emitting layer EML may include an organic or inorganic material that emits red, green, or blue light. The light emitting layer EML, which emits red, green, and blue light, may contain low-molecular or high-molecular organic materials. Although FIG. 1 illustrates the light emitting layer EML as a single layer, in practice, the light emitting layer EML may also include auxiliary layers such as an electron injection layer, an electron transfer layer, a hole transfer layer, and a hole injection layer on the top and bottom of the light emitting layer EML, such that the hole injection layer and the hole transfer layer are disposed on the bottom of the light emitting layer EML, and the electron transfer layer and the electron injection layer are disposed on the top of the light emitting layer EML.

Depending on the embodiment, the light emitting layer EML may include quantum dots. Quantum dots (hereinafter also referred to as semiconductor nanocrystals) may include group II-VI compounds, group III-V compounds, group IV-VI compounds, group IV elements or compounds, group I-III-VI compounds, group II-III-VI compounds, group I-II-IV-VI compounds, or a combination thereof. The quantum dots may not contain cadmium.

A second electrode E2 may be disposed on the pixel defining layer PDL and the light emitting layer EML. The second electrode E2 is also referred to as a cathode electrode, and may be formed of a transparent conductive layer containing indium tin oxide (ITO), indium zinc oxide (IZO), indium gallium zinc oxide (IGZO), and indium tin zinc oxide (ITZO). Additionally, the second electrode E2 may have translucent characteristics, and in this case, the second electrode E2 may form a microcavity together with the first electrode E1. According to the microcavity structure, the spacing and characteristics between both electrodes allow light of a specific wavelength to be emitted to the upper part, and as a result, red, green, or blue colors may be displayed.

The first electrode E1, the light emitting layer EML, and the second electrode E2 may form one light emitting device ED.

An encapsulation layer (not shown) may be disposed on the second electrode E2. The encapsulation layer may include at least one inorganic layer and at least one organic layer.

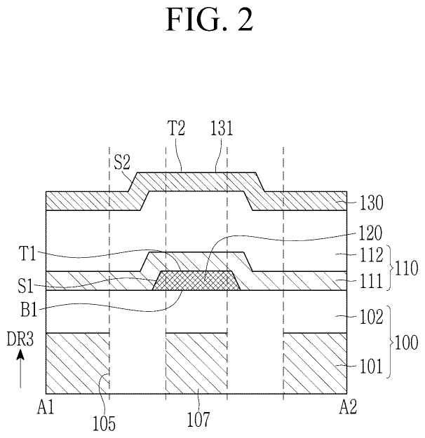

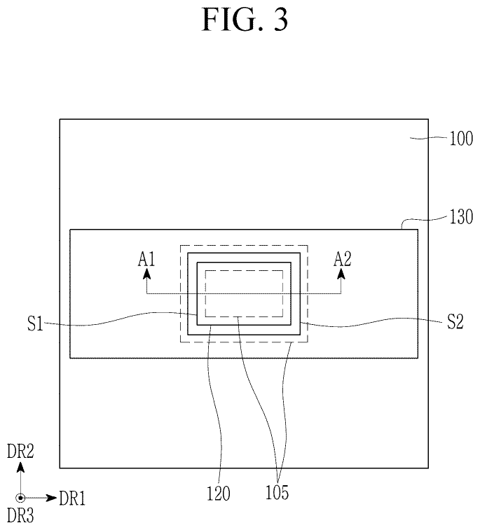

Hereinafter, the structure of a display device according to an embodiment will be described with reference to FIGS. 2 and 3. FIG. 2 is a cross-sectional view illustrating the substrate 100, the metal layer 120, and the semiconductor layer 130 in a display device according to an embodiment. FIG. 3 is a plan view illustrating the substrate 100, the buffer layer 110, the metal layer 120, and the semiconductor layer 130 in a display device according to an embodiment. FIG. 2 is a cross-sectional view of the display device shown in FIG. 3 taken along line A1-A2.

Referring to FIGS. 2 and 3, the substrate 100 may include at least one base layer 101. The base layer 101 may include a flexible material made of a polymer such as polyimide, polyamide, or polyethylene terephthalate.

The substrate 100 may further include at least one barrier layer 102 disposed on the base layer 101. The barrier layer 102 may be disposed between the metal layer 120 and the base layer 101. The barrier layer 102 may include an inorganic insulating material such as silicon nitride (SiNx), silicon oxide (SiOx), or silicon oxynitride (SiOxNy). The barrier layer 102 may have a single-layer or multi-layer structure containing the above inorganic insulating materials.

The metal layer 120 may be disposed between the substrate 100 and the buffer layer 110. The metal layer 120 may include an upper surface T1, a lower surface B1, and a side surface S1, and the area of the lower surface B1 of the metal layer 120 may be greater than the area of the upper surface T1. The side surface S1 is connected to the lower surface B1 and the upper surface T1, and may extend in a direction that is not parallel to the third direction DR3.

The buffer layer 110 may be disposed on the substrate 100 and the metal layer 120. The buffer layer 110 may include a first buffer layer 111 and a second buffer layer 112. The first buffer layer 111 may include silicon nitride (SiNx), and the second buffer layer 112 may include silicon oxide (SiOx). The hydrogen content of the first buffer layer 111 may be greater than the hydrogen content of the second buffer layer 112.

The semiconductor layer 130 may be disposed on the buffer layer 110. The semiconductor layer 130 may include a convex portion 131 corresponding to the upper surface Tl and the side surface S1 of the metal layer 120. The side surface S2 of the convex portion 131 of the semiconductor layer 130 may correspond to the side surface S1 of the metal layer 120, and the upper surface T2 of the convex portion 131 may correspond to the upper surface T1 of the metal layer 120. A step in the semiconductor layer 130 may be formed based on the side surface S2 of the semiconductor layer 130 where the shape of the side surface S1 of the metal layer 120 is transferred upward.

The base layer 101 of the substrate 100 may include an opening 105. The opening 105 of the base layer 101 may be in the form of a hole in the base layer 101 extending in the thickness direction of the base layer 101—that is, in the third direction DR3. The hole 105 may be in the form of a moat with an island 107 surrounded by the moat. Note that the substrate 100 may include an additional layer (not shown) below the base layer 101 to provide structure when forming the hole 105 during a manufacturing process. The additional layer may be a sacrificial layer that is removed during a later step in the manufacturing process.

Referring to FIG. 2, the side surface S1 of the metal layer 120 may be disposed inside the opening 105 of the base layer 101 in a plan view. The side surface S2 of the convex portion 131 of the semiconductor layer 130 may be disposed inside the opening 105 in a plan view. The opening 105 may overlap at least one of the side surface S1 of the metal layer 120 and the side surface S2 of the semiconductor layer 130 in the third direction DR3.

The opening 105 may be formed by patterning the base layer 101.

After forming a photoresist layer exposing a part of the base layer 101 on the base layer 101, the opening 105 may be formed by etching the base layer 101 exposed from the photoresist layer. Depending on the embodiment, the opening 105 may be formed using laser cutting. For example, the opening 105 may be formed by removing part of the base layer 101 through microprocessing using a femto or a pico laser. In this case, the laser may be irradiated to the lower or upper part of the base layer 101.

In the process of crystallizing the amorphous silicon layer of the semiconductor layer 130 into a polycrystalline silicon layer, heat energy may be discharged through the opening 105 of the substrate 100. Depending on the material of the base layer 101, the heat accumulated during the crystallization process may not be sufficiently discharged, resulting in a temperature increase at the upper boundary surface of the base layer 101, but according to the present embodiment, the temperature of the buffer layer 110 may increase less due to the heat discharge through the opening 105 of the base layer 101, and the diffusion of hydrogen contained in the buffer layer 110 towards the semiconductor layer 130 may be reduced. Accordingly, it is possible to prevent film bursting of the semiconductor layer 130 caused by hydrogen. Additionally, near the step formed in the semiconductor layer 130, the thickness of the semiconductor layer 130 is relatively thin and the surface energy is high, which is unstable and prone to film bursting, and in the present embodiment it is possible to prevent film bursting, especially in the vicinity of the step of the semiconductor layer 130.

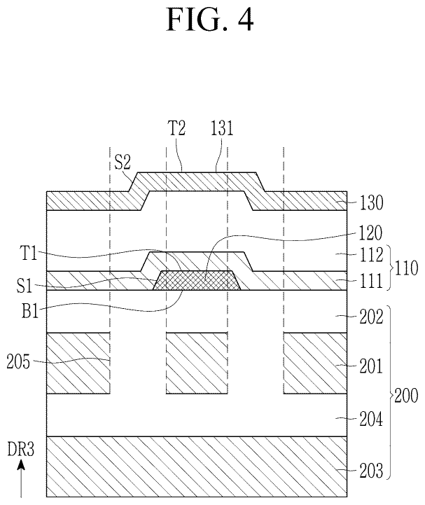

Hereinafter, a display device according to an embodiment will be described with reference to FIGS. 4 to 6. FIGS. 4 to 6 are cross-sectional views illustrating a substrate 200, the buffer layer 110, the metal layer 120, and the semiconductor layer 130 in a display device according to an embodiment.

Referring to FIGS. 4 to 6, the substrate 200 according to an embodiment may include a plurality of base layers 201 and 203. The substrate 200 may include a first base layer 201 and a second base layer 203 disposed below the first base layer 201. The first base layer 201 and the second base layer 203 may include a flexible material made of a polymer such as polyimide, polyamide, or polyethylene terephthalate.

The substrate 200 may include a plurality of barrier layers 202 and 204. The substrate 200 may include a first barrier layer 202 disposed on the first base layer 201 and a second barrier layer 204 disposed on the second base layer 203. The first barrier layer 202 and the second barrier layer 204 may include an inorganic insulating material such as silicon nitride (SiNx), silicon oxide (SiOx), or silicon oxynitride (SiOxNy).

Referring to FIG. 4, the first base layer 201 may include a first opening 205. The side surface S1 of the metal layer 120 may be disposed inside the first opening 205 in a plan view. Depending on the embodiment, the side surface S2 of the convex portion 131 of the semiconductor layer 130 may be disposed inside the first opening 205 in a plan view. The first opening 205 may overlap at least one of the side surface S1 of the metal layer 120 and the side surface S2 of the semiconductor layer 130 in the third direction DR3.

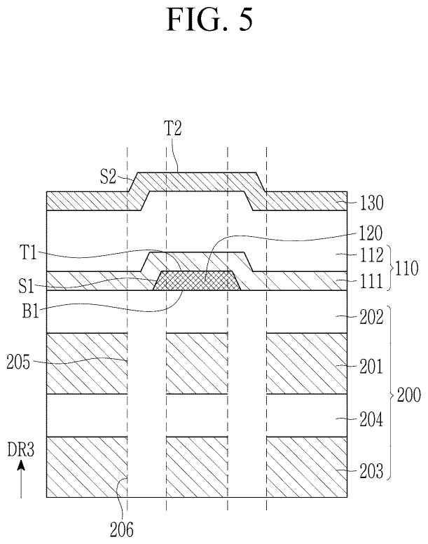

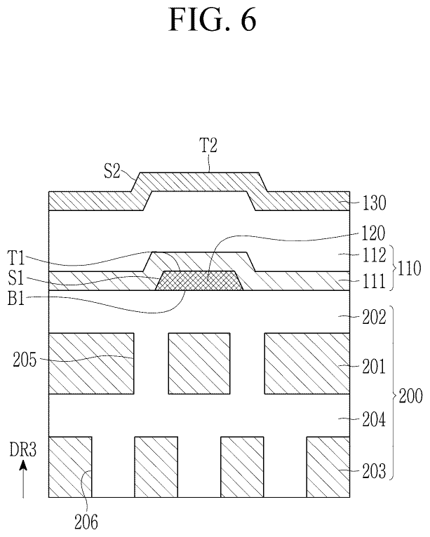

Referring to FIGS. 5 and 6, the first base layer 201 may include the first opening 205, and the second base layer 203 may include a second opening 206. The side surface S1 of the metal layer 120 may be disposed inside the first opening 205 or the second opening 206 in a plan view. Depending on the embodiment, the side surface S2 of the convex portion 131 of the semiconductor layer 130 may be disposed inside the first opening 205 or the second opening 206 in a plan view. The first opening 205 or the second opening 206 may overlap at least one of the side surface S1 of the metal layer 120 and the side surface S2 of the semiconductor layer 130 in the third direction DR3.

Referring to FIG. 5, the first opening 205 and the second opening 206 may be aligned in the third direction DR3. Specifically, the edge of the first opening 205 may be aligned with the edge of the second opening 206 corresponding to the first opening 205 in the third direction DR3. The first opening 205 and the second opening 206 may overlap in a plan view.

Referring to FIG. 6, the first opening 205 and the second opening 206 may be offset and misaligned in the third direction DR3. Specifically, the edge of the first opening 205 may be offset and misaligned with the edge of the second opening 206 in the third direction DR3.

In the process of crystallizing the amorphous silicon layer of the semiconductor layer 130 into a polycrystalline silicon layer, heat energy may be discharged through the first opening 205 or the second opening 206. Depending on the material of the base layers 201 and 203, the heat accumulated during the crystallization process may not be sufficiently discharged, resulting in a temperature increase at the upper boundary surface of the first base layer 201, but according to the present embodiment, the temperature of the buffer layer 110 may increase less due to the heat discharge through the first opening 205 or the second opening 206, and the diffusion of hydrogen contained in the buffer layer 110 towards the semiconductor layer 130 may be reduced. Accordingly, it is possible to prevent film bursting of the semiconductor layer 130 caused by hydrogen. Additionally, near the step formed in the semiconductor layer 130, the thickness of the semiconductor layer 130 is relatively thin and the surface energy is high, which is unstable and prone to film bursting, and the present embodiment may prevent film bursting, especially in the vicinity of the step of the semiconductor layer 130.

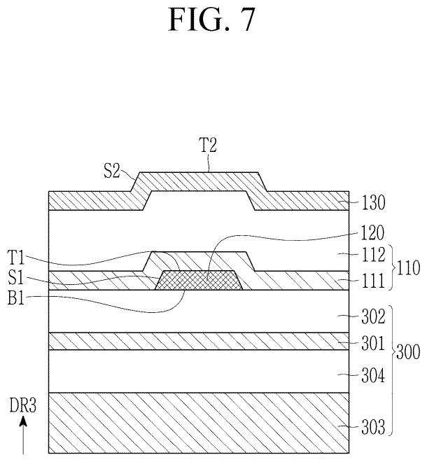

Hereinafter, a display device according to another embodiment will be described with reference to FIGS. 7 to 9. FIGS. 7 to 9 are cross-sectional views illustrating a substrate 300, the buffer layer 110, the metal layer 120, and the semiconductor layer 130 in a display device according to another embodiment.

Referring to FIGS. 7 to 9, the display device according to an embodiment is mostly the same as the display device according to the previously described embodiment, but may include the substrate 300. The substrate 300 according to an embodiment may include a plurality of base layers 301 and 303, and at least two of the plurality of base layers 301 and 303 may have different thicknesses.

The substrate 300 may include a first base layer 301 and a second base layer 303 disposed below the first base layer 301. The first base layer 301 and the second base layer 303 may include a flexible material made of a polymer such as polyimide, polyamide, or polyethylene terephthalate.

The substrate 300 may further include a first barrier layer 302 disposed on the first base layer 301 and a second barrier layer 304 disposed on the second base layer 303. The first barrier layer 302 and the second barrier layer 304 may include an inorganic insulating material such as silicon nitride (SiNx), silicon oxide (SiOx), or silicon oxynitride (SiOxNy).

Referring to FIG. 7, the thickness of the first base layer 301 may be thinner than the thickness of the second base layer 303. In an embodiment, the thickness of the first base layer 301 may be half of the thickness of the second base layer 303. For example, the first base layer 301 may be about 5 μm and the second base layer 303 may be about 10 μm. In this specification, “about” may include an error range of 1 μm.

In the process of crystallizing the amorphous silicon layer of the semiconductor layer 130 into a polycrystalline silicon layer, the thinner thickness of the first base layer 301 allows more heat energy to diffuse downward. Accordingly, the temperature of the buffer layer 110 increases less, and diffusion of hydrogen contained in the buffer layer 110 toward the semiconductor layer 130 may be reduced. Accordingly, it is possible to prevent film bursting of the semiconductor layer 130 caused by hydrogen.

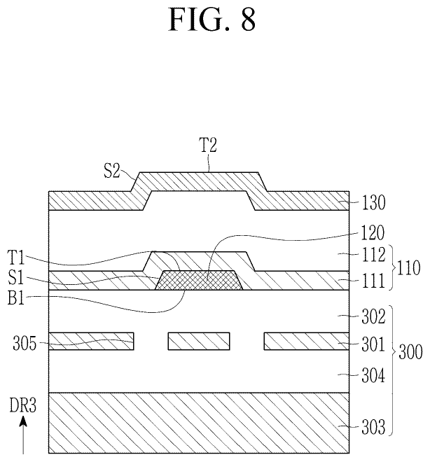

Referring to FIG. 8, the first base layer 301 may include a first opening 305. The side surface S1 of the metal layer 120 may be disposed inside the first opening 305 in a plan view. Depending on the embodiment, the side surface S2 of the convex portion 131 of the semiconductor layer 130 may be disposed inside the first opening 305 in a plan view. The first opening 305 may overlap at least one of the side surface S1 of the metal layer 120 and the side surface S2 of the semiconductor layer 130 in the third direction DR3.

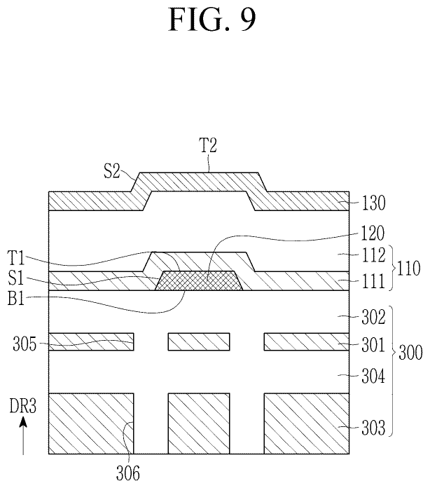

Referring to FIG. 9, the first base layer 301 may include the first opening 305, and the second base layer 303 may include a second opening 306. The side surface S1 of the metal layer 120 may be disposed inside the first opening 305 or the second opening 306 in a plan view. Depending on the embodiment, the side surface S2 of the convex portion 131 of the semiconductor layer 130 may be disposed inside the first opening 305 or the second opening 306 in a plan view. The first opening 305 or the second opening 306 may overlap at least one of the side surface S1 of the metal layer 120 and the side surface S2 of the semiconductor layer 130 in the third direction DR3.

Referring to FIG. 9, the first opening 305 and the second opening 306 may be aligned in the third direction DR3. Specifically, the edge of the first opening 305 may be aligned with the edge of the second opening 306 corresponding to the first opening 305 in the third direction DR3.

Depending on the embodiment, the first opening 305 and the second opening 306 may be offset and misaligned in the third direction DR3. Specifically, the edge of the first opening 305 may be offset and misaligned with the edge of the second opening 306 in the third direction DR3.

In the process of crystallizing the amorphous silicon layer of the semiconductor layer 130 into a polycrystalline silicon layer, heat energy may be discharged through the first opening 305 or the second opening 306. Depending on the material of the base layers 301 and 303, the heat accumulated during the crystallization process may not be sufficiently discharged, resulting in a temperature increase at the upper boundary surface of the first base layer 301, but according to the present embodiment, the temperature of the buffer layer 110 may increase less due to the heat discharged through the first opening 305 or the second opening 306, and the diffusion of hydrogen contained in the buffer layer 110 towards the semiconductor layer 130 may be reduced. Accordingly, it is possible to prevent film bursting of the semiconductor layer 130 caused by hydrogen. Additionally, near the step formed in the semiconductor layer 130, the thickness of the semiconductor layer 130 is relatively thin and the surface energy is high, which is unstable and prone to film bursting, and the present embodiment may prevent film bursting, especially in the vicinity of the step of the semiconductor layer 130.

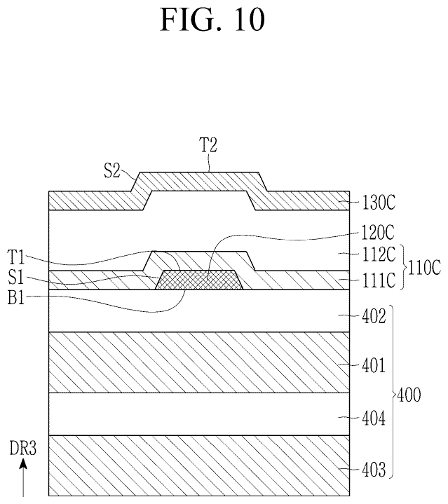

Hereinafter, a display device according to a comparative example will be described with reference to FIG. 10. FIG. 10 is a cross-sectional view illustrating a substrate 400, a buffer layer 110C, a metal layer 120C, and a semiconductor layer 130C of the display device according to the comparative example. The buffer layer 110C may include a first buffer layer 111C and a second buffer layer 112C.

Referring to FIG. 10, the display device according to the comparative example is mostly the same as the display device according to the embodiment of the present disclosure described above, but may include the substrate 400. The substrate 400 may include a plurality of base layers 401 and 403. The substrate 400 may include a first base layer 401 and a second base layer 403 disposed below the first base layer 401.

The substrate 400 may include at least one barrier layer 402 and 404. The substrate 400 may further include a first barrier layer 402 disposed on the first base layer 401 and a second barrier layer 404 disposed on the second base layer 403.

In the display device according to the comparative example, the base layers 410 and 403 of the substrate 400 do not include openings.

Additionally, in the display device according to the comparative example, the thickness of the first base layer 401 is substantially the same as the thickness of the second base layer 403. For example, the first base layer 401 and the second base layer 403 may be about 10 μm. In this specification, “substantially” and “about” may include an error range of 1 μm.

Since the base layers 401 and 403 do not include openings, heat accumulated during the process of crystallizing the amorphous silicon layer of the semiconductor layer 130C into a polycrystalline silicon layer is not sufficiently discharged. A temperature rise occurs at the upper boundary surface of the first base layer 401, causing the temperature of the buffer layer 110C to rise, and hydrogen contained in the buffer layer 110 diffuses toward the semiconductor layer 130. Therefore, film bursting of the semiconductor layer 130 due to hydrogen occurs.

In particular, near the step formed in the semiconductor layer 130, the thickness of the semiconductor layer 130 is relatively thin and the surface energy is high, which is unstable and prone to film bursting.

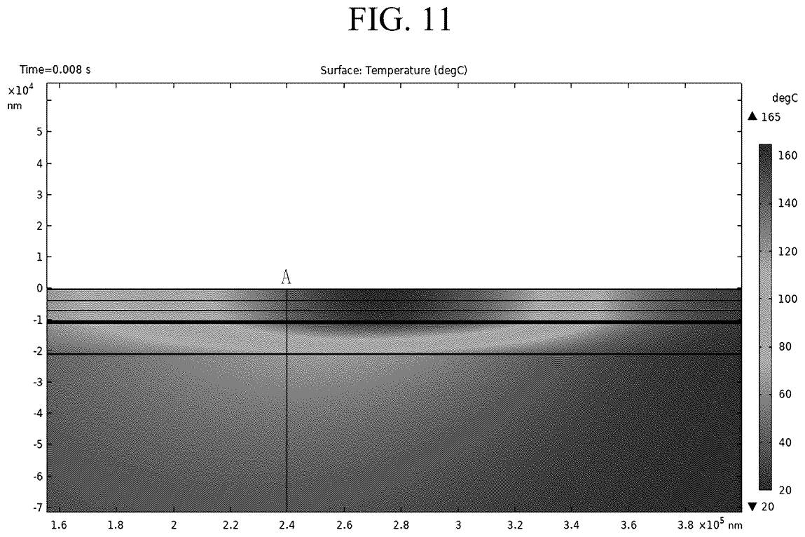

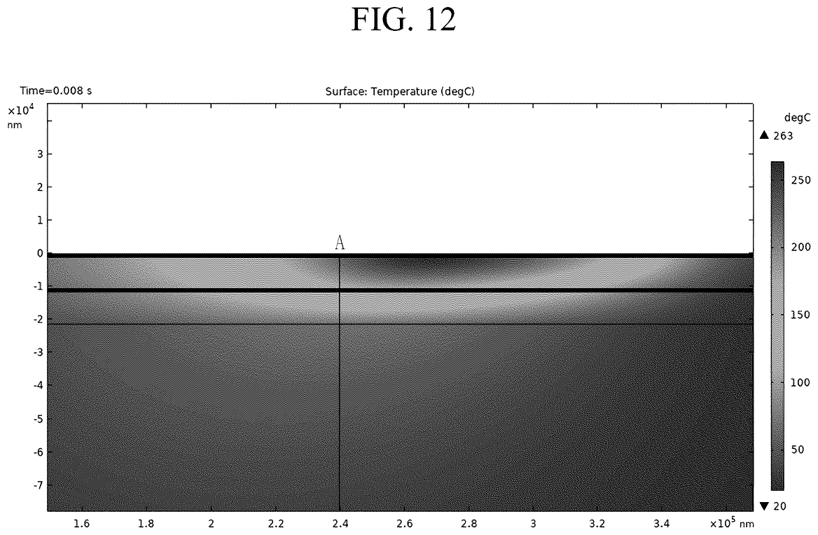

Hereinafter, the temperature distribution of the substrate of the display device according to an embodiment of the present disclosure and the display device according to the comparative example will be described with reference to FIGS. 11 and 12 along with FIGS. 5 and 10 described above. FIGS. 11 and 12 are graphs illustrating a temperature of the substrate 200 from the semiconductor layer 130 of a display device according to an embodiment and a temperature of the substrate 400 from the semiconductor layer 130C of a display device according to the comparative example, respectively.

FIG. 11 is a graph illustrating the temperature of the semiconductor layer 130, the buffer layer 110, and the substrate 200 when the crystallization time (t) is 0.008 s when the amorphous silicon layer of the semiconductor layer 130 is crystallized into a polycrystalline silicon layer using the SLA method, in a display device according to an embodiment of the present disclosure. A cross-sectional view of a display device according to an embodiment is shown in FIG. 5. Referring to FIG. 5, the first base layer 201 may include the first opening 205 and the second base layer 203 may include the second opening 206. The side surface S1 of the metal layer 120 may be disposed inside the first opening 205 and the second opening 206 in a plan view.

The x-axis of FIG. 11 shows the length of the semiconductor layer 130 in the first direction in the cross-sectional view of FIG. 5. The y-axis shows the depth of the display device starting at 0 (“zero”) based on the upper surface of the semiconductor layer 130 in the cross-sectional view of FIG. 5.

FIG. 12 is a graph illustrating the temperature of the semiconductor layer 130C, the buffer layer 110C, and the substrate 400 when the crystallization time (t) is 0.008 s when the amorphous silicon layer of the semiconductor layer 130C is crystallized into a polycrystalline silicon layer using the SLA method, in a display device according to the comparative example. A cross-sectional view of the display device according to the comparative example is shown in FIG. 10.

The x-axis of FIG. 12 shows the length of the semiconductor layer 130C in the first direction in the cross-sectional view of FIG. 10. The y-axis shows the depth of the display device starting at 0 (“zero”) based on the upper surface of the semiconductor layer 130C in the cross-sectional view of FIG. 10.

Referring to the vertical line A (x=2.4×10⁵ nm) shown in FIG. 11, the display device according to an embodiment has a temperature of the substrate 200 in the range of 120° C. to 160° C. when y=−1 μm.

Referring to the vertical line A (x=2.4×10⁵ nm) shown in FIG. 12, the display device according to the comparative example has a temperature of the substrate 400 in the range of 150° C. to 200° C. when y=−1 μm.

Referring to FIGS. 11 and 12, the temperature of the substrate 200 of the display device according to an embodiment is lower than the temperature of the substrate 400 of the display device according to the comparative example.

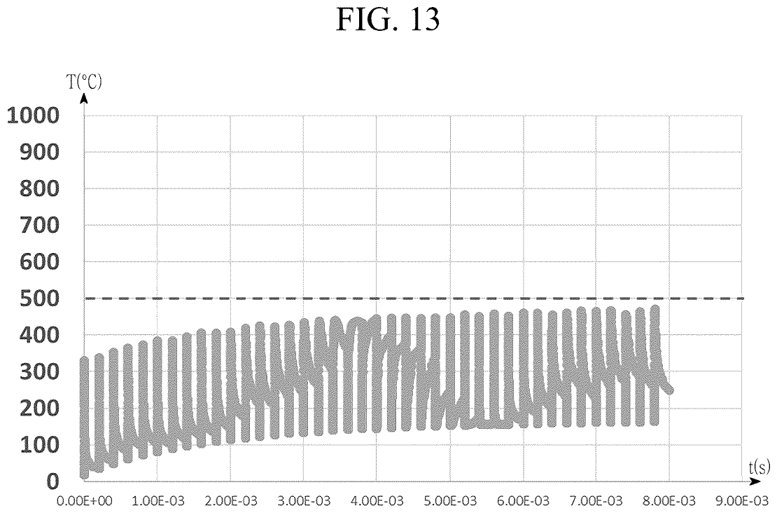

Hereinafter, with reference to FIGS. 13 to 15 along with FIGS. 5, 7, and 10 described above, a display device according to an embodiment of the present disclosure, a display device according to another embodiment, and the temperature distribution of the buffer layer of the display device according to the comparative example will be described. FIGS. 13 to 15 are graphs illustrating temperatures of the buffer layer 110 of the display device according to an embodiment, the buffer layer 110 of the display device according to another embodiment, and the buffer layer 110C of the display device according to the comparative example, respectively.

FIG. 13 is a graph showing a temperature (T) of the buffer layer 110 according to the crystallization time (t) when the amorphous silicon layer of the semiconductor layer 130 is crystallized into a polycrystalline silicon layer using the SLA method, in a display device according to an embodiment of the present disclosure. A cross-sectional view of a display device according to an embodiment is shown in FIG. 5. Referring to FIG. 13, the temperature (T) of the buffer layer 110 does not exceed 500° C. over the time (t).

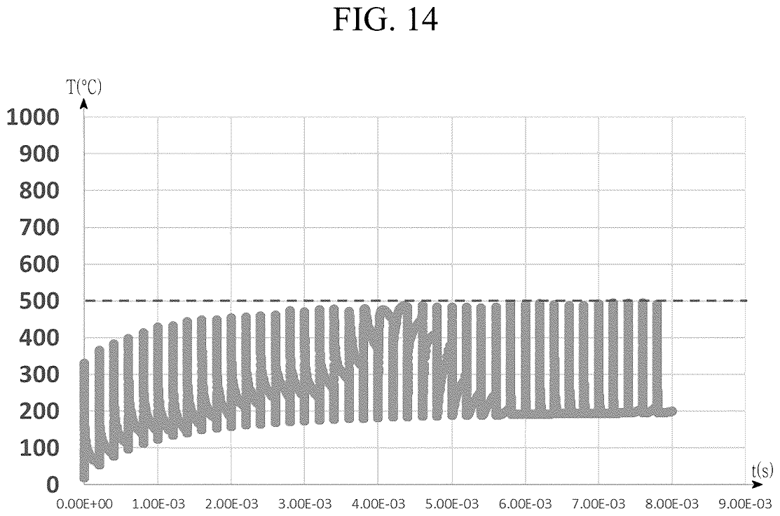

FIG. 14 is a graph showing the temperature of the buffer layer 110 according to the crystallization time (t) when the amorphous silicon layer of the semiconductor layer 130 is crystallized into a polycrystalline silicon layer using the SLA method, in a display device according to another embodiment of the present disclosure. A cross-sectional view of a display device according to another embodiment is shown in FIG. 7. Referring to FIG. 14, the temperature (T) of the buffer layer 110 does not exceed 500° C. over the time (t).

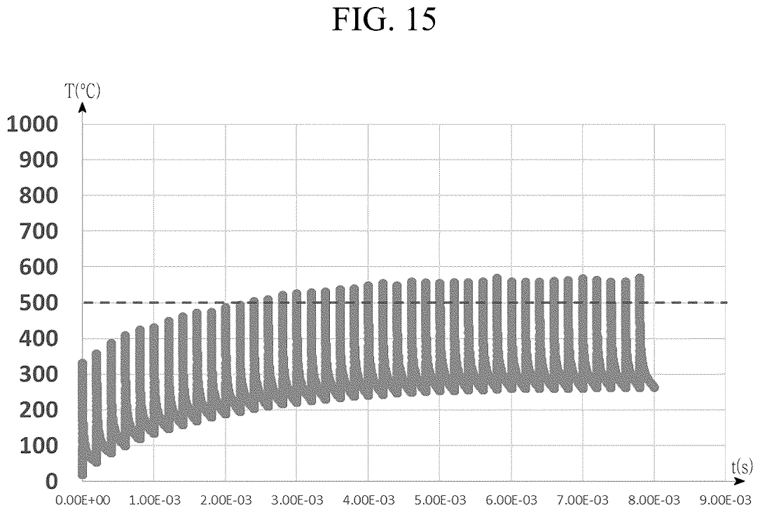

FIG. 15 is a graph showing the temperature of the buffer layer 110C according to the crystallization time (t) when the amorphous silicon layer of the semiconductor layer 130C is crystallized into a polycrystalline silicon layer using the SLA method, in a display device according to the comparative example. A cross-sectional view of the display device according to the comparative example is shown in FIG. 10. Referring to FIG. 15, the temperature (T) of the buffer layer 110C according to the comparative example exceeds 500° C. from about t=2.00×10⁻³ s and reaches a temperature close to 600° C. at about t=5.00×10⁻³ s.

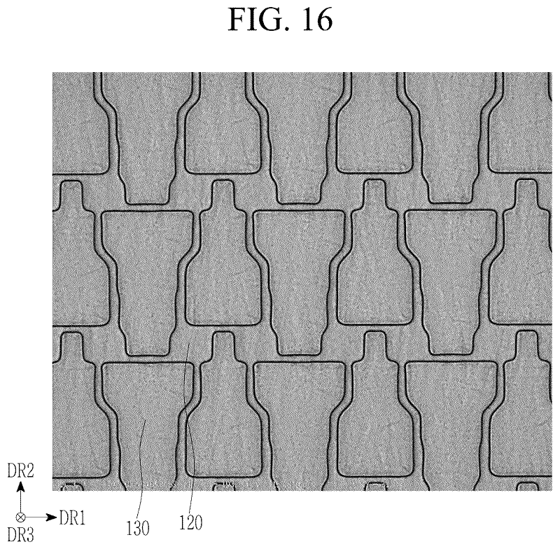

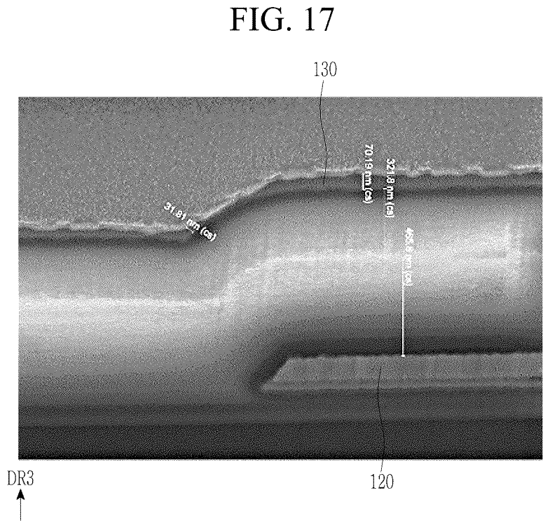

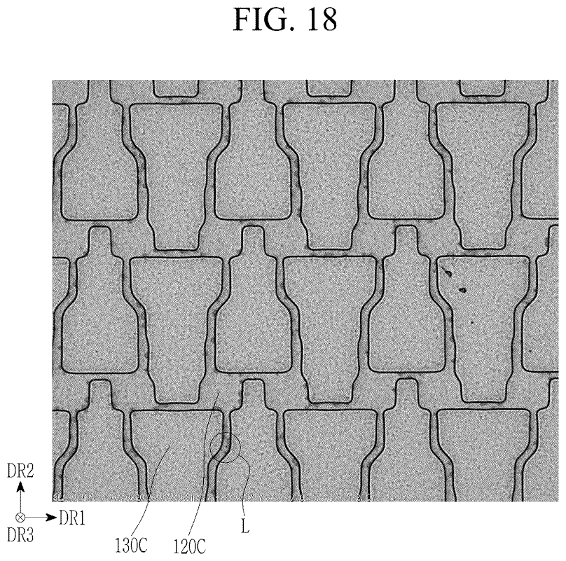

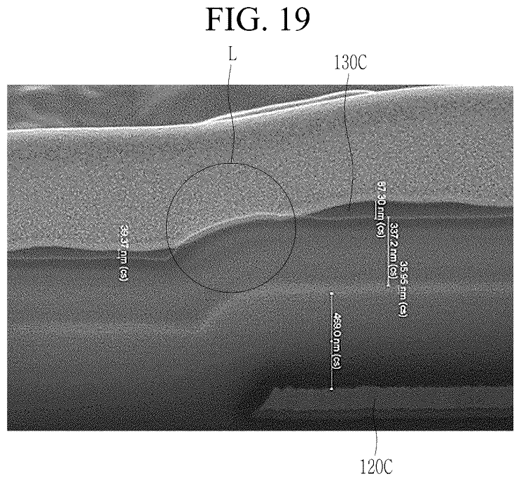

Hereinafter, the forms of the metal layer and semiconductor layer of the display device according to an embodiment of the present disclosure and the display device according to the comparative example will be described with reference to FIGS. 16 to 19 along with FIGS. 5 and 10 described above. FIGS. 16 and 17 are photographs showing a part of a display device according to an embodiment. FIGS. 18 and 19 are photographs showing a part of the display device according to the comparative example shown in FIG. 10.

FIG. 16 is a photograph showing the planar shape of the metal layer 120 and the semiconductor layer 130 after crystallizing the amorphous silicon layer of the semiconductor layer 130 into a polycrystalline silicon layer using the SLA method, in a display device according to an embodiment of the present disclosure. FIG. 16 shows the planar shape of the patterned metal layer 120 and the semiconductor layer 130 covering the metal layer 120. FIG. 17 is a photograph showing the cross-sectional shape of the metal layer 120 and the semiconductor layer 130 after crystallizing the amorphous silicon layer of the semiconductor layer 130 into a polycrystalline silicon layer using the SLA method, in a display device according to an embodiment of the present disclosure. Referring to FIGS. 16 and 17, it can be seen that no film bursting occurred in the film of the semiconductor layer 130 after crystallization.

FIG. 18 is a photograph showing the planar shape of the metal layer 120C and the semiconductor layer 130C after crystallizing the amorphous silicon layer of the semiconductor layer 130C into a polycrystalline silicon layer using the SLA method, in a display device according to the comparative example. FIG. 19 is a photograph showing the cross-sectional shape of the metal layer 120C and the semiconductor layer 130C after crystallizing the amorphous silicon layer of the semiconductor layer 130C into a polycrystalline silicon layer using the SLA method, in a display device according to the comparative example. Referring to FIGS. 18 and 19, it can be seen that the film of the semiconductor layer 130C after crystallization bursts, resulting in a loss (L) of the semiconductor layer 130C.

A display device according to an embodiment may be applied to various electronic devices. An electronic device according to an embodiment may include the display device, and may further include modules or devices having additional functions other than the display device.

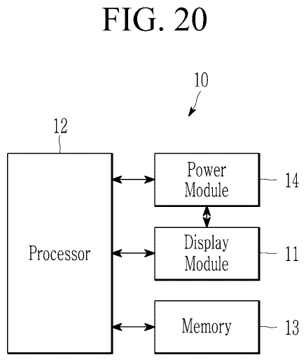

FIG. 20 is a block diagram of an electronic device according to an embodiment. Referring to FIG. 20, the electronic device 10 according to an embodiment may include a display module 11, a processor 12, a memory 13, and a power module 14.

The processor 12 may include at least one of a central processing unit (CPU), an application processor (AP), a graphic processing unit (GPU), a communication processor (CP), an image signal processor (ISP), and a controller.

The memory 15 may store data information necessary for operations of the processor 12 or the display module 11. When the processor 12 executes an application stored in the memory 15, video data signals and/or input control signals are transmitted to the display module 11, and the display module 11 can process the received signals to output video information through the display screen.

The power module 14 may include a power supply module such as a power adapter or battery device, and a power conversion module that converts the power supplied by the power supply module to generate the power necessary for the operation of the electronic device 10.

At least one of components of the electronic device 10 may be included within the display device according to the above-described embodiments. Additionally, some of the individual modules that are functionally included within a single module may be incorporated into the display device, while others may be provided separately from the display device. For example, the display device may include the display module 11, while the processor 12, memory 13, and power module 14 may be provided in a form of other devices within the electronic device 10 that are not part of the display device.

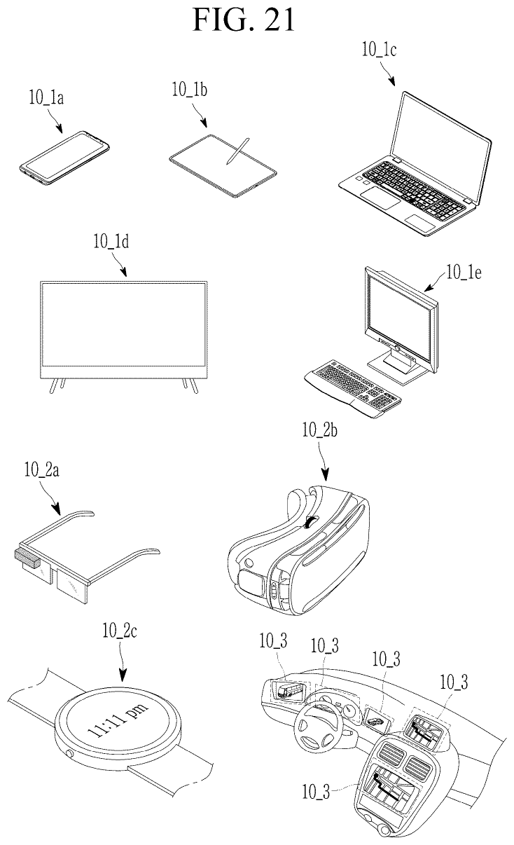

FIG. 21 shows schematic diagrams of electronic devices according to various embodiments.

Referring to FIG. 21, various electronic devices with the display device according to the embodiments may include not only image display electronic devices such as smartphones 10_1a, tablet PCs 10_1b, laptops 10_1c, TVs 10_1d, desktop monitors 10_1e, but also wearable electronic devices with display modules such as smart glasses 10_2a, head-mounted displays 10_2b, smart watches 10_2c, as well as automotive electronic devices with display modules 10_3 such as those placed on car dashboards, center fascias, CID (Center Information Display), room mirror displays, and so on.

While embodiments of the present disclosure have been described, it should be understood that the disclosure is not limited to the disclosed embodiments, but on the contrary, is intended to cover various modifications and equivalent arrangements included within the spirit and scope of the appended claims.

What is claimed is:

1. A display device, comprising:
a substrate including a first base layer and a first barrier layer;
a metal layer disposed on the substrate;
a buffer layer disposed on the metal layer; and
a semiconductor layer disposed on the buffer layer,
wherein the first base layer comprises a first opening, and
a side surface of the metal layer is disposed inside the first opening in a plan view.

2. The display device of claim 1, wherein
the semiconductor layer comprises a convex portion corresponding to the side surface of the metal layer and an upper surface of the metal layer, and
a side surface of the convex portion is disposed inside the first opening in a plan view.

3. The display device of claim 1, further comprising
a second base layer disposed below the first base layer.

4. The display device of claim 3, wherein
a thickness of the first base layer is thinner than a thickness of the second base layer.

5. The display device of claim 4, wherein
the thickness of the first base layer is half the thickness of the second base layer.

6. The display device of claim 3, wherein
the second base layer comprises a second opening.

7. The display device of claim 6, wherein
the side surface of the metal layer is disposed inside the second opening in a plan view.

8. The display device of claim 7, wherein
an edge of the first opening is aligned with an edge of the second opening corresponding to the first opening.

9. The display device of claim 6, wherein
an edge of the first opening is not aligned with an edge of the second opening.

10. The display device of claim 6, wherein
the first opening does not overlap the second opening.

11. The display device of claim 6, wherein
a side surface of a convex portion is disposed inside the second opening in a plan view.

12. A method of manufacturing a display device, comprising:
forming a first base layer;
forming a first opening in the first base layer by patterning the first base layer;
forming a first barrier layer on the first base layer;
forming a metal layer on the first barrier layer;
forming a buffer layer on the metal layer; and
forming a semiconductor layer on the buffer layer,
wherein a side surface of the metal layer is disposed inside the first opening in a plan view.

13. The method of manufacturing the display device of claim 12, wherein
the forming of the first opening comprises forming the first opening by irradiating a laser to an upper surface or a lower surface of the first base layer.

14. The method of manufacturing the display device of claim 12, further comprising:
before the forming of the first base layer, forming a second base layer; and
forming a second barrier layer on the second base layer.

15. The method of manufacturing the display device of claim 14, wherein
a thickness of the first base layer is thinner than a thickness of the second base layer.

16. The method of manufacturing the display device of claim 14, further comprising:
after the forming of the second base layer, forming a second opening by patterning the second base layer.

17. The method of manufacturing the display device of claim 16, wherein
the forming of the second opening comprises forming the second opening by irradiating a laser to an upper surface or a lower surface of the second base layer.

18. The method of manufacturing the display device of claim 16, wherein
the side surface of the metal layer is disposed inside the second opening in a plan view.

19. The method of manufacturing the display device of claim 18, wherein
an edge of the first opening is aligned with an edge of the second opening corresponding to the first opening.

20. An electronic device comprising a processor and a display device,
the display device comprising:
a substrate including a first base layer and a first barrier layer;
a metal layer disposed on the substrate;
a buffer layer disposed on the metal layer; and
a semiconductor layer disposed on the buffer layer,
wherein the first base layer comprises a first opening, and
a side surface of the metal layer is disposed inside the first opening in a plan view.
